(19) United States
(12) Patent Application Publication
(10) Pub. No.: US 2002/0000677 A1
(43) Pub. Date: Jan. 3, 2002

(54) Part maintenance device of semiconductor processing system and method for operating the same

(75) Inventors: Kazushi Tahara, Yamanashi (JP); Akira Obi, Yamanashi (JP)

Correspondence Address: Finnegan, Henderson, Farabow, Garrett & Dunner L.L.P., 1300 I Street, N.W., Washington, DC, 20005-3315, US

(73) Assignee: TOKYO ELECTRON LIMITED

(21) Appl. No.: 09/893,628

(22) Filed: Jun. 29, 2001

(30) Foreign Application Priority Data
Jun. 30, 2000 (JP) JP2000-199137

(51) Int. Cl. H01L 23/58

(52) U.S. Cl. 257/798

(57) ABSTRACT

A part maintenance device of a semiconductor processing system and a method for operating the same wherein the abnormal operation of parts of the system is detected, thereby preventing the system breakdown and accident before their occurrence. The normal operation time of a part and the allowable limit value levels corresponding thereto are set and stored, the allowable limit value levels being a plurality of discrete levels (Step 101). Then, the system is actually driven (Step 102) and the actual operation time of the part is measured (Step 103). In the next, the allowable limit value levels of the normal operation time of the part and the actual normal operation time of the part are compared with each other thereby the need of the part maintenance being judged (Step 104). If it is judged that the part is OK, the part will be allowed to run continuously thereafter. If judged NG, a post-processing will be executed corresponding to the value level (Step 105). As the post-processing, there can be considered the issuance of an alarm instruction, a termination instruction of system driving, a spare part supply instruction for replacement, an estimation instruction of the future part life, and so forth.

### BACKGROUND OF THE INVENTION

1. Field of the Invention

The present invention relates to a part maintenance device of a semiconductor processing system and a method for operating the part maintenance device as well. In this specification, a term ‘part’ is used for specifying a thing that constitutes a part of a semiconductor processing system and is driven by a predetermined part driving device, for instance a gate valve or the like.

2. Prior Art

It is already well known that in the process of manufacturing the semiconductor device, so many processings and treatments have to be executed, for instance a chemical etching treatment, a thin film formation processing, an ashing treatment, a spattering processing, and so forth. At the same time, a variety of semiconductor processing systems are used in compliance with such processings and treatments. For instance, one example will be seen in a processing system of the multi-chamber type having a so-called cluster tool structure, which enables a plurality of processings and treatments to be executed within a single system. The system of this kind is constructed such that a plurality of vacuum processing and/or treatment chambers are connected with a common transfer chamber, and an objective substrate to be processed and/or treated, for instance a semiconductor wafer, is taken in and taken out from a carry-in and carry-out chamber connected with the vacuum transfer chamber through a preparatory vacuum chamber having a load-lock function. Therefore, the system of this type is suitable for advancing the high integration of the semiconductor device as well as for increasing the high throughput of the same, and also for preventing the objective to be processed and/or treated from various contaminants.

In case of the semiconductor processing system as described above, however, it generally includes a lot of portions moving or to be moved. Therefore, unless they are sufficiently stabilized, its operation speed is made slower and mechanical reliability would be lowered, and it becomes hard for the system to display its full ability and performance adequately. Furthermore, in case the system is once broken down, it cannot help being stopped for a long time for restoration thereof, which would worsen the throughput of the semiconductor device production.

In order to prevent the system from being broken down, the Japanese patent publication No. 2-181299 proposes an automatic breakdown diagnostic system provided with functions of perceiving the usable life of respective portions of the system, selecting portions to be examined, which are likely to fall in the abnormal condition, and checking them. In order to prevent the system from being broken down before its occurrence, to increase the production yield of the semiconductor device being processed, and to maintain a predetermined throughput, the part maintenance in the system comes to be one of the most important things to be done. Speaking of the part maintenance in the system, what has been done so far is at most to check and judge the accumulated operation time and/or the number of operation times of the part and to provide the system with such a maintenance function as automatic issuance of an alarm when the breakdown takes place.

However, in case of the judgement of the part condition relying on the check of the accumulated operation time and the number of operation times, it has not always coincided with presence of the actual abnormal condition in the system. For instance, it actually happens that some parts break down before they reach their prescribed operation time and/or the number of operation times while some others normally work well even exceeding their prescribed operation time and/or the number of operation times. Accordingly, it has been desired to establish not the judgement standard relying only on the accumulated operation time and/or the number of operation times, but the judgement standard much more reasonably meeting the actual part operation.

The present invention has been made in view of such problems as described above, and the main object thereof is to provide a part maintenance device of the semiconductor processing system and a method for operating it, by which the abnormal operation of the part can be detected, thereby preventing the system from being broken down well before it occurs.

### SUMMARY OF THE INVENTION

In order to solve the problems as described above, according to the first aspect of the invention, there is provided a part maintenance device of a semiconductor processing system wherein the part is driven by a part driving portion. This part maintenance device includes a preliminary setting means for preliminarily setting and storing the normal operation time of the part and the allowable limit value levels corresponding to the normal operation time; a measurement means for measuring the actual operation time of the part; and a maintenance judgement means for judging the operation condition of the part by comparing the actual operation time with the allowable limit value levels corresponding to the normal operation time. With such a structure of the device as described above, it becomes possible to catch the actual operation condition of each part, on the basis of which the more realistic judgement becomes possible. Thus, it becomes possible to detect the abnormal condition of each part and to prevent the system from the breakdown and accident before their occurring. Furthermore, the invention is generally applicable to the semiconductor processing system of any type, that is, not only the semiconductor processing system of the multi-chamber type as described above but also the one of the in-line type and others. At that time, the above-mentioned measurement means may be arranged to measure the operation time of the part driving portion.

According to another aspect of the invention, there is provided a part maintenance device of a semiconductor processing system wherein the part is driven by a part driving portion. This part maintenance device includes a preliminary setting means for preliminarily setting and storing the change with the passage of time (referred to as ‘time-passage change’ hereinafter) with regard to the normal operation of the part and the allowable limit value levels corresponding to the time-passage change; a measurement means for measuring the time-passage change in respect to the actual operation of the part; and a maintenance judgement means for judging the operation condition of the part by comparing the time-passage change in respect to the actual operation with the allowable limit value levels of the time-passage change in respect to the normal operation. According to such a structure of the device as described above, it becomes possible to catch the actual operation condition of each part, on the basis of which the more realistic judgement can be made. Thus, it becomes possible to detect the abnormal condition of each part and to prevent the system from the breakdown and accident before their occurring. At that time, the above-mentioned measurement means may be arranged to measure the time-passage change with regard to the operation of the part driving portion.

According to still another aspect of the invention, there is provided a method for executing the maintenance of a part which is driven by a part driving portion in a semiconductor processing system. This method includes the steps of setting the normal operation time of the part and the allowable limit value levels corresponding to the above normal operation time; measuring the actual operation time of the part; and comparing the actual operation time of the part as measured with the allowable limit value levels in respect to the normal operation time of the part, thereby executing the judgement with respect to the maintenance of the part. At that time, it is preferable that the allowable limit value levels are separately set to take a plurality of limit value levels and that different post-processings can be suitably carried out corresponding to each limit value level. With this separate setting of the allowable limit value levels, it becomes possible to take a fine and suitable transaction corresponding to the operation condition of each part. Various post-processings corresponding to the characteristic of each part can be considered, for instance, issuance of an alarm instruction, a termination instruction of device driving, a spare part supply instruction for replacement, an estimation instruction of the future part life, and so forth. With the instruction like this, the system operator can recognize where, what and how the abnormal condition of the system would be and can timely take the pertinent transaction, for instance terminating the operation of the device to avoid the danger, ordering spare parts for replacement in advance, and so on. Therefore, it can be avoided that the device operation is stopped for a long time and the throughput is lowered extremely.

According to still another aspect of the invention, there is provided a method for executing the maintenance of a part which is driven by a part driving portion in a semiconductor processing system. This method includes the steps of setting the time-passage change in respect to the normal operation of the part and the allowable limit value levels corresponding to said normal operation; measuring the time-passage change in respect to the actual operation of the part; and comparing the time-passage change in respect to the actual operation of the part as measured with the allowable limit value levels in respect to the normal operation of the part, thereby executing the judgement with respect to the maintenance of the part. At that time, it is preferable that the allowable limit value levels are separately set to take a plurality of limit value levels and that different post-processings can be suitably carried out corresponding to each limit value level. With this separate setting of the allowable limit value levels, it becomes possible to take a fine and suitable transaction corresponding to the condition of each part. Various post-processings corresponding to the characteristic of each part can be considered, for instance, issuance of an alarm instruction, a termination instruction of device driving, a spare part supply instruction for replacement, an estimation instruction of the future part life, and so forth. With the instruction like this, the system operator can recognize where, what and how the abnormal condition of the system would be and can timely take the pertinent transaction, for instance terminating the operation of the device to avoid the danger, ordering spare parts for replacement in advance, and so on. Therefore, it can be avoided that the device operation is stopped for a long time and the throughput is lowered extremely.

### DETAILED DESCRIPTION OF THE PREFERRED EMBODIMENTS

In the following, the semiconductor processing system preferably embodied according to the invention will be described in detail with reference to the accompanying drawings. In the following descriptions and the accompanying drawings, like constituents of the invention having almost similar function and structure are designated with like reference numerals and characters, thereby omitting the redundant and repetitive description about such constituents.

### BRIEF DESCRIPTION OF THE DRAWINGS

The above and other features of the invention and the concomitant advantages will be better understood and appreciated by persons skilled in the field to which the invention pertains in view of the following description given in conjunction with the accompanying drawings which illustrate preferred embodiments.

FIG. 1 is a schematic plan view of a semiconductor processing system according to the invention.

FIG. 2 is a schematic side view of a semiconductor processing system according to the invention.

FIG. 3 is a block diagram illustrating a part maintenance device according to an embodiment of the invention.

FIG. 4 is a flowchart showing a method for a part maintenance according to a first embodiment of the invention.

FIG. 5 is an explanatory diagram for explaining an example wherein the method shown in FIG. 4 is applied to a gate valve.

FIG. 6 is a flowchart for use in explanation of a part maintenance method according to a second embodiment of the invention.

FIG. 7 is a graph showing the time-passage change with regard to the gate valve operation.

FIG. 8 is a graph showing the time-passage change with respect to the operation of a gate valve driving means operation.

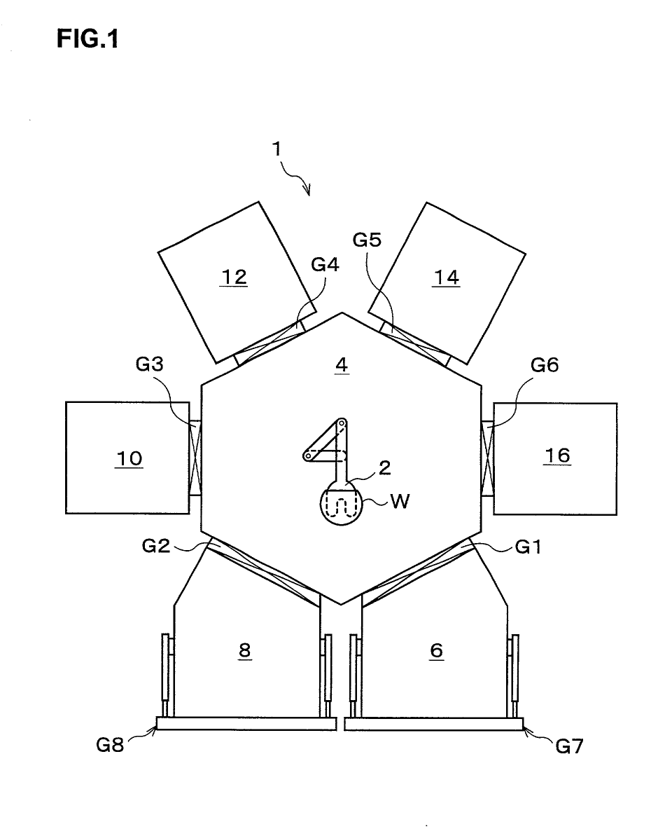

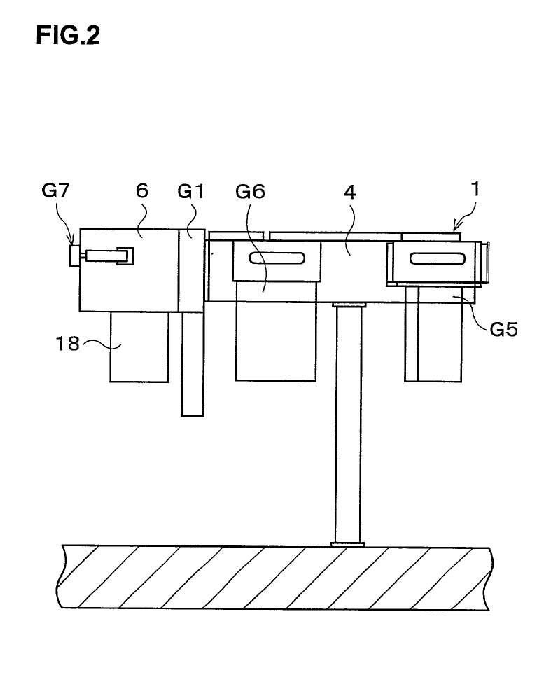

FIGS. 1 and 2 respectively show schematic plan and side views of a semiconductor processing system of the multi-chamber type. To start with, the whole structure of this processing system 1 will be described with reference to FIGS. 1 and 2. The processing system 1 is made up of a vacuum transfer chamber 4 having a transfer arm 2 for transferring an objective to be treated, for instance a semiconductor wafer W, the first through sixth gate valves G1˜G6, the first and second load-lock chambers 6 and 8, and the first through fourth vacuum treatment chambers 10, 12, 14 and 16 for applying predetermined various treatments to the objective semiconductor wafer W, two load-lock chambers 6, 8 and four vacuum treatment chambers 10, 12, 14 and 16 being arranged around the vacuum transfer chamber 4 through one of six gate valves G1˜G6, respectively.

The first and second load-lock chambers 6, 8 carry in and out the semiconductor wafer W between the vacuum transfer chamber 4 and the outside thereof under the atmospheric pressure, keeping the pressure reduced atmosphere inside the vacuum transfer chamber 4 unchanged as far as possible. The inside pressure of the first and second load-lock chambers 6, 8 can be properly controlled and set by means of a pressure regulation mechanism 18 which is made up of a vacuum pump and a gas supply system and installed respectively under the load-lock chambers 6, 8. Each opening of the first and second load-lock chambers 6, 8 formed on the atmospheric pressure side is openably shut with airtightness by means of the seventh and eighth gate valves G7 and G8. The opening and shutting operation of the first through eighth gate valves G1˜G8 is carried out by a driving mechanism (not shown) which drives a valve body forming the essential part of each gate valve to move it up and down. FIG. 2 is a diagram indicating such a state that the first through fourth vacuum treatment chambers 10, 12, 14 and 16 have been disconnected from the processing system 1.

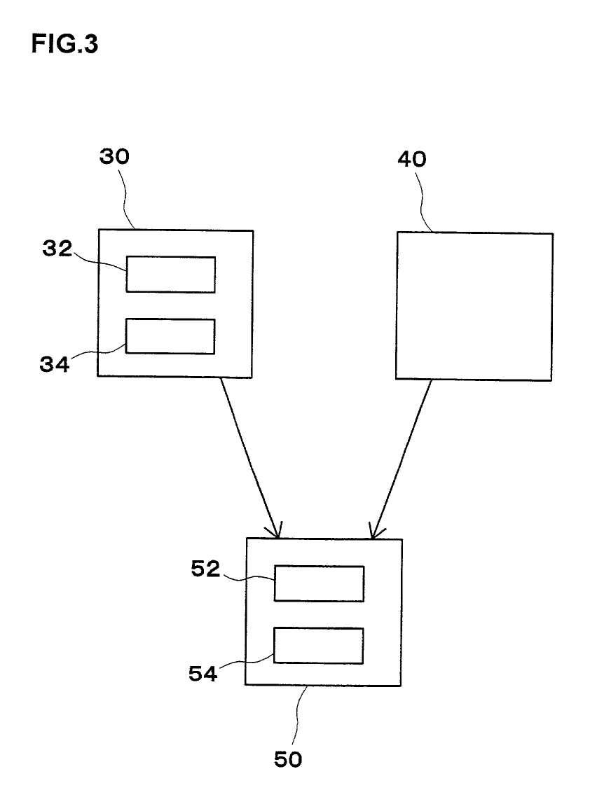

FIG. 3 is a block diagram illustrating a part maintenance device of the semiconductor processing system according to the invention. The part maintenance device includes a preliminary setting means 30, a measurement means 40, and a maintenance judgement means 50. The preliminary setting means 30 includes a setting portion 32 for preliminarily setting the normal operation time of the part (the typical length of time required for the normal operation of the part) and allowable limit value levels corresponding thereto, or the time-passage change with regard to the normal operation of the part (the ratio of the temporal change with regard to the normal operation of the part) and allowable limit value levels corresponding thereto, and also a memory portion 34 for storing those which have been preliminarily set by the setting portion 32, that is, the normal operation time of the part and allowable limit value levels corresponding thereto, or the time-passage change with regard to the normal operation of the part and allowable limit value levels corresponding thereto. The measurement means 40 is a means for measuring the actual operation time of the part (the time actually required for the part operatation), or the time-passage change with respect to the normal operation of the part (the ratio of the temporal change with respect to the actual operation of the part). In this case, the measurement means 40 may be arranged either to directly measure the operation of the part itself or to measure the operation of a part driving means indirectly. Furthermore, the maintenance judgement means 50 further includes a comparison portion 52 for comparing the actual part operation time with the allowable limit value levels corresponding to the normal part operation time, or comparing the time-passage change in respect to the normal operation of the part with the allowable limit value levels corresponding to the time-passage change of the normal part operation, and a judgement portion 54 for judging the operational condition of the part based on the comparison result attained from the comparison portion 52.

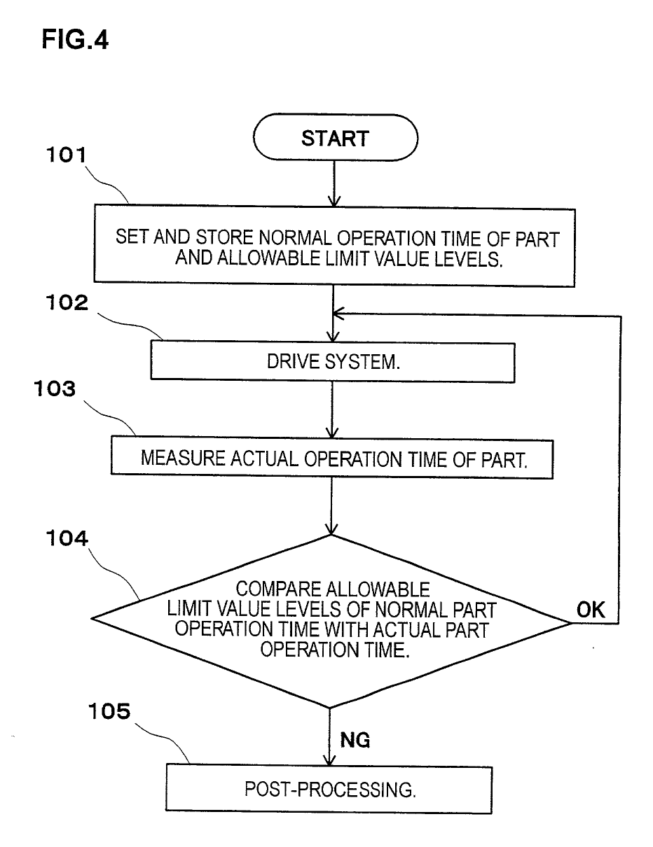

FIG. 4 is a flowchart for describing a part maintenance method of the semiconductor processing system according to a first embodiment of the invention. In this embodiment, the operation time of the part is used as the judgement standard for judging the need of part maintenance. Supposing a normal part at first, the normal operation time of this part and the allowable limit value levels corresponding thereto are set and stored, the allowable limit value levels being a plurality of discrete levels (Step 101). Then, the system is actually driven (Step 102) and the actual operation time of the part is measured (Step 103). After termination of driving the device, the allowable limit value levels of the normal part operation time as set at Step 101 and the actual normal part operation time as measured at Step 103 are compared with each other, thereby judging the need of the part maintenance (Step 104). If it is judged that the part is OK, that is, the part has cleared up the judgement standard, the part will be allowed to be used continuously thereafter. If judged NG, the most suitable post-processing will be executed as a troubleshooter (Step 105) by taking account of the allowable limit value levels as set and stored in the above. Various processings might be considered as the post-processing, for instance, issuance of various instructions such as an alarm instruction, a termination instruction of device driving, a spare part supply instruction for replacement, an estimation instruction of the future part life, and so forth.

In the above explanation, it is described that the measurement of the actual part operation time at Step 103 is carried out by directly measuring the operation time of the part itself. It may be allowed, however, to indirectly measure the actual part operation time by way of the part driving means for driving the part.

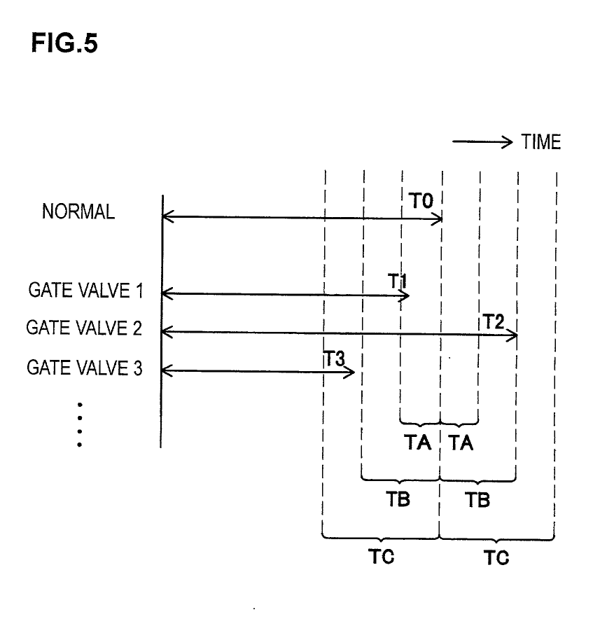

FIG. 5 is an explanatory diagram for explaining a concrete case in which the method as described above is applied to a gate valve as a real part. Again, supposing a normal gate valve, then the normal gate valve operation time T0 and three allowable limit value levels T0±TA, T0±TB, and T0±TC (where TA<TB<TC) are set and stored. Then, the system is driven, during which the actual operation time of the gate valve is measured, for instance the actual operation time of the gate valve 1 having been measured as Ti. After terminating the system driving, the allowable limit value levels as set corresponding to the normal operation time of the gate valve and the actual operation time of the gate valve as measured are compared with each other, from the result of which the need of part maintenance is judged. Here, let us provisionally define the relation between the above comparison result and the post-processing corresponding thereto as follows. For instance, if the actual operation time T of the gate valve is in the range of T0−TA<T<T0+TA, it is judged that the gate valve is OK, that is, the gate valve has cleared up the judgement standard. If the time T is in the range of T0−TB<T<T0−TA or T0+TA<T<T0+TB, it is judged that the gate valve is NG and issuance of alarm instruction is needed. If the time T is in the range of T0−TC<T<T0−TB or T0+TB<T<T0+TC, it is judged that the gate valve is also NG and issuance of termination instruction of the system driving is needed.

As will be seen from FIG. 5, as the actual operation time T1 of the gate valve 1 is in the range of T0−TA<T1 <T0+TA, it obtains the judgement of OK. In case of the gate valve 2 as shown in FIG. 5, its actual operation time T2 is in the range of T0+TA<T2<T0+TB, so that it receives the judgement that the gate valve 2 is NG and issuance of alarm instruction is needed. In case of the gate valve 3, its actual operation time T3 is in the range of T0−TC<T3<T0−TB, so that it also receives the judgement that the gate valve 3 is NG and issuance of the termination instruction of the device driving is needed. Consequently, the gate valve 1 is allowed to be used continuously thereafter while the gate valves 2 and 3 are dealt with according to the alarm instruction and the termination instruction of the device driving, respectively.

As described above, the abnormal operation of the part can be detected by comparing the actual operation time of the part with the allowable limit value levels corresponding thereto, so that it becomes possible to make a judgement well meeting the more realistic gate valve operation. Furthermore, as the allowable limit value levels corresponding to the normal part operation time is set in the form of a plurality of discrete limit value levels, each gate valve can be properly dealt with according to the corresponding limit value level. This means that the trouble, accident, or the like of the system can be prevented before their occurrence.

In the above case, it is described that the actual operation time of the gate valve is determined by measuring the operation time of the gate valve itself. However, it is possible to determine the operation time from the measurement of the operation time of a driving motor for driving the gate valve. There is no difference between effects that are obtained by the above two ways of measurement, that is, the same effect is obtainable.

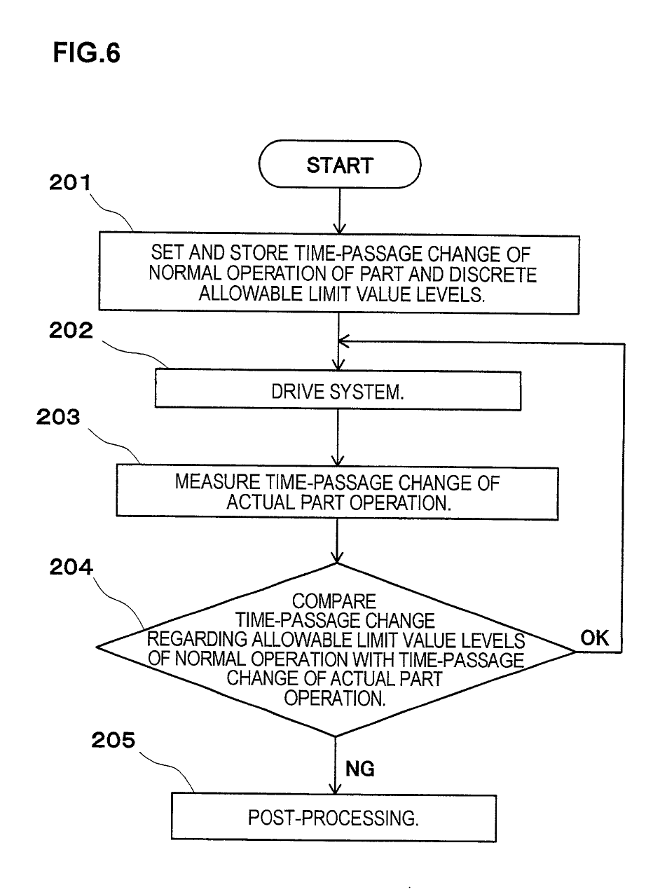

Now, let us move to the explanation about the part maintenance method of the semiconductor processing system according to the second embodiment of the invention. FIG. 6 is a flowchart for explaining the part maintenance method of the semiconductor processing system embodying the invention. In this embodiment, a time-passage change of the part operation is used as a judgement standard for judging the need of the part maintenance. First of all, supposing a normal part, there are set and stored the time-passage change in regard to the normal operation of that part and the allowable limit value levels corresponding thereto (Step 201), the allowable limit value levels being discrete. Then, the device is actually driven (Step 202) and the time-passage change in respect to the actual operation of the part is measured (Step 203). After termination of driving the system, the allowable limit value levels corresponding to the time-passage change with regard to the normal operation of the part as set in Step 201 and the time-passage change with regard to the actual operation of the part as measured in Step 203 are compared with each other, thereby judging the need of the part maintenance (Step 204). If it is judged that the part is OK, that is, the part has cleared the judgement standard, the part will be used continuously thereafter. If judged NG, the most suitable post-processing will be executed as a troubleshooter by taking account of the levels as set and stored above (Step 205). There would be considered as the post-processing, for instance, issuance of alarm instruction, termination instruction of device driving, supply instruction of the spare part for replacement, estimation instruction of the future part life, and so forth.

In the above case, it is described that the measurement of the actual time-passage change in regard to the actual operation of the part at Step 203 is carried out by measuring the operation of the part itself. It may be allowed, however, to measure the time-passage change in respect to the actual operation of a driving means for driving the part.

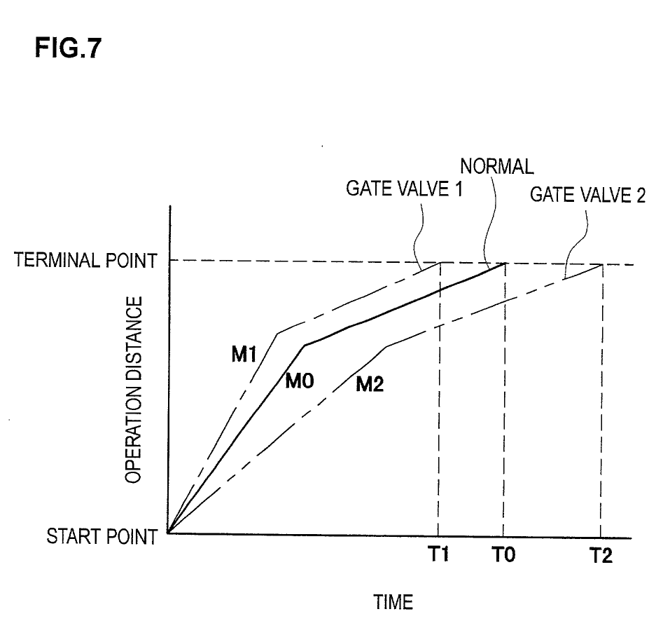

FIG. 7 is an explanatory diagram for explaining the case in which this part maintenance method is applied to an actual gate valve as a part. FIG. 7 is a graph of which the abscissa represents the time while the ordinate does the operation distance of the gate valve, and describes the time-passage change of the gate valve operation, more particularly, the open and shut operation of the gate valve operation from its start point to its terminal point. In FIG. 7, a solid line describes the time-passage change of the normal operation by the above supposed normal gate valve while a single dotted chain line and a double dotted chain line describe the time-passage changes of the operation by actual gate valves 1 and 2, respectively. Strictly speaking, these time-passage changes should be drawn with curves, not bent straight lines. However, for just simplification, the graph is drawn by approximating curves with the bent straight lines. The inflexion point (bent point) as will be seen on way of each straight line is naturally born as the result that in order to open and shut the gate valve, the gate valve has to be first lifted in one direction and then moved in the other direction.

Here, let us consider and use the operation speed as a parameter describing the time-passage change of the gate valve operation. The operation speed can be obtained from the inclination of the straight lines of FIG. 7. At first, supposing a normal gate valve, let the inclination of a line in the graph, which extends the start point up to the inflexion point and represents the time-passage change with regard to the normal operation of the gate valve be M0. Furthermore, let two allowable limit value levels M0±MA and M0±MB (where MA<NB) with regard to M0 be set and stored. In the next, the system is driven during which the time-passage change of the actual gate valve operation is measured. At this time, the inclination of the line from the start point up to the inflexion point is Ml, which represents the time-passage change with regard to the actual operation of the gate valve 1. After termination of the system driving, the allowable limit value levels as set with regard to the time-passage change of the normal gate valve operation and the time-passage change with respect to the actual operation of the measured gate valve are compared with each other, thereby judging the need of the part maintenance from the result of the above comparison.

Here, similar to the concrete case described in connection with FIG. 5, again let us provisionally define the relation between the above comparison result and the post-processing as follows. For instance, if the time-passage change M of the actual gate valve operation is in the range of M0−MA<M<M0+MA, it is judged that the gate valve is OK. If the time-passage change M is in the range of M0−MB<M<M0−MA or M0+MA<M<M0+MB, it is judged that the gate valve is NG and issuance of termination instruction of the system driving is needed. For instance, the time-passage change M1 of the gate valve 1 is in the range of M0−MA<Ml<M0+MA, it is judged that the gate valve is OK. If the inclination M2 of the line extending from the start point to the inflexion point, which describes the time-passage change in respect to the actual operation of the gate valve 2, is in the range of M0−MB<M2<M0-MA, it is judged that the gate valve 2 is NG and the termination of the system driving is needed. In this case, the gate valve 1 will be still allowed to be used continuously while the gate valve 2 is dealt with according to the instruction of terminating operation.

Accordingly, the abnormal operation of the part can be detected by comparing the allowable limit value levels of the time-passage change in regard to the normal operation of the part with the time-passage change in regard to the actual operation of the part, so that it becomes possible to make a judgement well meeting the more realistic part operation. Furthermore, as the allowable limit value levels of the time-passage change in regard to the normal operation is discretely set in the form of a plurality of levels, each part can be dealt with by the post-processing properly meeting its level. This means that the trouble, accident, or the like of the system can be prevented before their occurrence.

In the example as described above, the inclination of the line indicating the gate valve movement from the start point to the inflexion point has been considered as that which represents the time-passage change with respect to the normal operation of the gate valve. However, it may be possible to consider the inclination of the line extending from the inflexion point to the terminal point thereof in the same manner. Furthermore, it may be also possible to use the combination of both of the above two inclinations. Still further, the linear approximated operation speed is considered as a parameter indicating the time-passage change of the operation. However, some other parameter may be used. For instance, if the graph of FIG. 7 is drawn with curves, it may be possible to first measure the operation speed at each time point and then to calculate and use the amount of variation obtained from the measured maximum and minimum values.

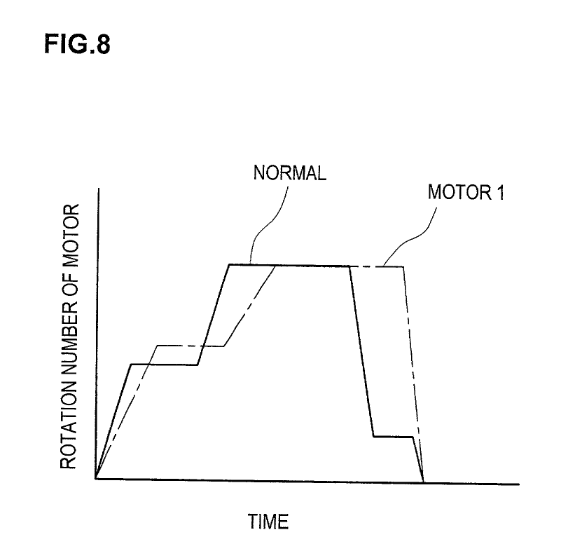

Still further, when measuring the time-passage change with regard to the actual operation of the gate valve, it may be possible to measure the time-passage change with regard to the operation of a motor which is a means for driving the gate valve. In FIG. 8, the graph drawn with a solid line represents the time-passage change of the normal operation of a supposed motor while the graph drawn with a single dotted chain line represents time-passage change in respect to the operation of an actual motor 1. In this case, similar to the cases as described above, the time-passage change of the actual operation is measured and then compared with the allowable limit value levels of the time-passage change of the normal operation, thereby the maintenance judgement being executed with the same effect as that obtained by the other ways described above.

In the above, the invention has been described by way of the example in which it is applied to the gate valve, but the invention is not limited to this example. Needless to say, the invention is applicable to other parts related to the semiconductor processing system.

The judgement method according to the invention making use of the operation time and the time-passage change of the operation can work in combination with such a prior art judgement method as makes use of the accumulated operation time and the number of the times of operations. In such a case, the trouble, accident, or the like of the system would be more effectively prevented before their occurrence.

For example, the preliminary setting means and the maintenance judgement means, except for the measurement means, in the part maintenance device can be included in a remotely-located computer and the like connected through the Internet, to facilitate the part maintenance from the remote location.

The invention has been described so far by way of some of preferred embodiments thereof with reference to the accompanying drawings. Needless to say, however, the invention can not be limited by these embodiments. It is apparent that any one who has an ordinary skill in the art is able to make various changes and modifications within the technical thoughts as recited in the scope of claim for patent as per attached hereto, and it is understood that those changes and modifications are covered by the technical scope of the invention, naturally.

According to the invention as has been described in detail thus far, the abnormal operation of the part can be detected by comparing the allowable limit value levels of the time-passage change in regard to the normal operation of the part with the time-passage change in regard to the actual operation of the part, so that it becomes possible to make a judgement well meeting the more realistic part operation. Furthermore, as the allowable limit value levels with respect to the time-passage change of the normal operation is discretely set in the form of a plurality of levels, each part can be dealt with by the post-processing properly meeting its level. Accordingly, the trouble, accident, or the like of the system can be prevented before their occurrence.

What is claimed is:

1. A part maintenance device of a semiconductor processing system wherein said part is driven by a part driving portion, said part maintenance device comprising:
a preliminary setting means for preliminarily setting and storing the normal operation time of said part and the allowable limit value levels corresponding thereto;
a measurement means for measuring the actual operation time of said part; and
a maintenance judgement means for judging the operation condition of said part by comparing said actual operation time with the allowable limit value levels of said normal operation time.

2. A part maintenance device claimed as claim 1 wherein said measurement means measures the operation time of said part driving portion.

3. A part maintenance device claimed as claim 1 wherein said part is a gate valve.

4. A part maintenance device of a semiconductor processing system wherein said part is driven by a part driving portion, said part maintenance device comprising:
a preliminary setting means for preliminarily setting and storing the change with the passage of time (again referred to as ‘time-passage change’ hereinafter) with regard to the normal operation of said part and the allowable limit value levels corresponding to said time-passage change;
a measurement means for measuring the time-passage change in respect to the actual operation of said part; and
a maintenance judgement means for judging the operation condition of said part by comparing the time-passage change in respect to said actual operation with the allowable limit value levels of the time-passage change in respect of said normal operation.

5. A part maintenance device claimed as claim 4 wherein said measurement means measures the time-passage change in respect to the operation of said part driving portion.

6. A method for executing the maintenance of a part which is driven by a part driving portion in a semiconductor processing system, said method comprising the steps of:
setting the normal operation time of said part and the allowable limit value levels corresponding to said normal operation time;
measuring the actual operation time of said part; and
comparing the actual operation time of said part as measured with the allowable limit value levels in respect to the normal operation time of said part, thereby executing the judgement with respect to the maintenance of said part.

7. A method as claimed in claim 6 wherein said allowable limit value levels are discretely set in a plurality of levels and different post-processings for the part is executed corresponding to each level.

8. A method as claimed in claim 7 wherein said post-processing includes issuance of an alarm instruction.

9. A method as claimed in claim 7 wherein said post-processing includes issuance of an instruction for terminating the system operation.

10. A method as claimed in claim 7 wherein said post-processing includes issuance of a spare part supply instruction for replacement.

11. A method as claimed in claim 7 wherein said post-processing includes issuance of an estimation instruction for estimating the future life of the part.

12. A method as claimed in claim 6 wherein said part is a gate valve.

13. A method for executing the maintenance of a part which is driven by a part driving portion in a semiconductor processing system, said method comprising the steps of:
setting the time-passage change in respect to the normal operation of said part and the allowable limit value corresponding thereto;
measuring the time-passage change in respect to the actual operation of said part; and
comparing the time-passage change in respect to the actual operation of said part as measured with the allowable limit value levels of the time-passage change in respect to the normal operation of said part, thereby executing the judgement with respect to the maintenance of said part.

14. A method as claimed in claim 13 wherein said allowable limit value levels are discretely set in a plurality of levels and the different post-processing for the part is executed corresponding to each level.

15. A method as claimed in claim 14 wherein said post-processing includes issuance of an alarm instruction.

16. A method as claimed in claim 14 wherein said post-processing includes issuance of an instruction for terminating the system operation.

17. A method as claimed in claim 14 wherein said post-processing includes issuance of a spare part supply instruction for replacement.

18. A method as claimed in claim 14 wherein said post-processing includes issuance of an estimation instruction for estimating the future life of the part.

19. A method as claimed in claim 13 wherein said part is a gate valve.
